(19) United States
(12) Patent Application Publication
(10) Pub. No.: US 2008/0020494 A1
(43) Pub. Date: Jan. 24, 2008

(54) Film formation apparatus, precursor introduction method and film formation method

(75) Inventor: Hiroyuki Ode, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., Tokyo (JP)

(21) Appl. No.: 11/819,019

(22) Filed: Jun. 25, 2007

(30) Foreign Application Priority Data
Jul. 24, 2006 (JP) 2006-200979

(51) Int. Cl. B05C 11/00; C23C 16/52; H01L 21/00

(52) U.S. Cl. 438/5; 118/712; 427/8; 257/E21.002

(57) ABSTRACT

The present invention has an object of providing: a film formation apparatus for forming a film by a supercritical film formation method using at least a solid precursor wherein the solid precursor can be introduced into a film formation chamber at constant speed; a method for introducing the precursor; and a film formation method.

The present invention is to use a film formation apparatus having: a film formation chamber; a preparation device for preparing a solid precursor solution by dissolving the solid precursor in supercritical carbon dioxide; a first supercritical carbon dioxide feeding line for feeding supercritical carbon dioxide into the preparation device; a detector for monitoring concentration of the solid precursor in the solid precursor solution; a flow rate adjusting means for controlling the flow rate of the solid precursor solution discharged from the preparation device so that introduction speed of the solid precursor to be introduced into the film formation chamber becomes constant by feeding back the concentration of the solid precursor obtained in the detector; and a solid precursor introduction line for introducing the solid precursor solution discharged from the preparation device into the film formation chamber.

### BACKGROUND OF THE INVENTION

1. Field of the Invention

The present invention relates to: a film formation apparatus suitable for film formation of a composite material film such as insulation films for DRAM capacitor and High-k films; a method for introducing a precursor for the film formation; and a method for the film formation.

2. Description of the Related Art

In CVD method and ALD method which are conventional film formation methods, a precursor reagent as a raw material is introduced in volatilized condition into a film formation chamber. When a plurality of precursor reagents are used, however, the vapor pressure of each precursor reagent may increase. In such a case, it is extremely difficult to control the introduction amounts of respective precursor reagents to attain a suitable mixing ratio.

For example, in formation of STO (Sr—Ti—O film) which is believed to be promising as a high-k film of the next generation, known as a precursor reagent of Ti are those having relatively high volatility, and introduction thereof is relatively easy. However, a precursor reagent of Sr has in general lower volatility as compared with a precursor reagent of Ti. Therefore, it is extremely difficult to introduce these two precursor reagents at any proportion, resultantly, formation of an STO film having any composition ratio becomes difficult. In order to volatilize a precursor reagent which has low volatility, higher temperature is necessary, thus, causing thermal decomposition of the precursor reagent in some cases.

As is understood from recent rising of the ALD method, it is becoming important to improve step coverage and film quality by forming a film in Layer-by-Layer fashion not by introducing a precursor reagent into a film formation chamber in one shot but by introducing a precursor reagent while controlling the amount.

As described above, it is a problem to introduce a plurality of precursor reagents constantly into a film formation chamber at any ratio while controlling the introduction amount (introduction speed).

Recently, as a novel film formation technology for production of semiconductor devices of the next generation, a film formation technology using supercritical carbon dioxide (supercritical film formation method) is paid to attention. Particularly, High-k films and ferroelectric films are reported in, for example, Japanese Patent Application Laid-Open Nos. 2000-357686, 2003-213425, 2004-186305 and 2003-514115. Superiority of the supercritical film formation method is said to include various matters such as increase of precursor reagents capable of being used, improvement in step coverage, and improvement of the quality of a film.

### SUMMARY OF THE INVENTION

However, under the present situation, film formation by the supercritical film formation method has not attained practical level. One reason for this is believed that film formation apparatuses and film formation methods for extracting potentials of the supercritical film formation method to the utmost extent have not been investigated sufficiently. Particularly, to show sufficient superiority of the supercritical film formation method in a part of introduction into a film formation chamber (including volatilization process) of a precursor reagent, which often causes problems in the CVD method and ALD method, is expected to be an important point exerting an influence on further practical application of the supercritical film formation method.

For example, in a method of dissolving a precursor reagent in supercritical carbon dioxide and thereafter simply introducing the flow of the solution into a film formation chamber (a method of continuously introducing while keeping the same flow rate of supercritical carbon dioxide at an inlet port and an outlet port of a film formation chamber), the concentration of the precursor reagent becomes dilute in continuing liquid feeding, thus, constant introduction of a precursor reagent at constant speed cannot be attained. Particularly, for those in solid state among precursor reagents (solid precursors), it is difficult to attain constant introduction at constant speed.

The present invention has an object of providing: a film formation apparatus for forming a film by a supercritical film formation method using at least a solid precursor wherein the solid precursor can be introduced into a film formation chamber at constant speed; a method for introducing the precursor; and a film formation method.

The present invention resides in a film formation apparatus for forming a film using at least a solid precursor, having:

a film formation chamber;

a preparation device for preparing a solid precursor solution by dissolving the solid precursor in supercritical carbon dioxide;

a first supercritical carbon dioxide feeding line for feeding supercritical carbon dioxide into the preparation device;

a detector for monitoring concentration of the solid precursor in the solid precursor solution;

a flow rate adjusting means for controlling flow rate of the solid precursor solution discharged from the preparation device so that introduction speed of the solid precursor to be introduced into the film formation chamber becomes constant by feeding back the concentration of the solid precursor obtained in the detector; and

a solid precursor introduction line for introducing the solid precursor solution discharged from the preparation device into the film formation chamber.

As the detector, for example, a UV-V is measuring apparatus or an FT-IR measuring apparatus is used.

It is preferable that the film formation apparatus of the present invention further has a mixing device for mixing the solid precursor solution discharged from the preparation device with another substance. It is also preferable that the film formation apparatus of the present invention further has a second supercritical carbon dioxide feeding line for feeding supercritical carbon dioxide into the mixing device.

According to the film formation apparatus having the mixing device, a composite material film can also be formed by using a plurality of precursors containing at least a solid precursor.

When a composite material film is formed using a plurality of solid precursors, the film formation apparatus may have a constitution which has a plurality of the preparation devices, the first supercritical carbon dioxide feeding lines, the detectors, the flow rate adjusting means and the solid precursor introduction lines, wherein a plurality of the solid precursor solutions discharged from a plurality of the preparation devices are mixed together in the mixing device.

When a composite material film is formed using a solid precursor and a liquid precursor, the film formation apparatus may have a constitution which further has a liquid precursor introduction line for introducing a liquid precursor into the mixing device.

When a composite material film is formed using a solid precursor and a gas precursor, the film formation apparatus may have a constitution which further has a gas precursor introduction line for introducing a gas precursor into the film formation chamber.

The film formation apparatus as described above is suitable as a film formation apparatus equipped on a semiconductor device production apparatus.

The present invention resides in a precursor introduction method for introducing at least a solid precursor into a film formation chamber, having the steps of:

(a) preparing a solid precursor solution by dissolving the solid precursor in supercritical carbon dioxide in a preparation device;

(b) monitoring concentration of the solid precursor in the solid precursor solution;

(c) controlling flow rate of the solid precursor solution discharged from the preparation device so that introduction speed of the solid precursor to be introduced into the film formation chamber becomes constant by feeding back the concentration of the solid precursor obtained by the monitoring; and

(d) introducing the solid precursor solution discharged from the preparation device into the film formation chamber.

The monitoring in the step (b) is carried out by, for example, UV-V is measurement or FT-IR measurement.

It is preferable that the precursor introduction method of the present invention further has the steps of:

(e) additionally mixing supercritical carbon dioxide with the solid precursor solution discharged from the preparation device; and

(f) controlling feeding speed of the supercritical carbon dioxide to be additionally mixed so that flow rate of supercritical carbon dioxide to be introduced into the film formation chamber becomes constant.

According to the precursor introduction method of the present invention, it is also possible to introduce a plurality of precursors containing at least a solid precursor into a film formation chamber.

When a plurality of solid precursors are mixed together and introduced into a film formation chamber, the precursor introduction method may have a constitution, wherein the steps (a) to (c) are performed on each of a plurality of the solid precursors, which further has the step of:

(g) mixing a plurality of the solid precursor solutions discharged from a plurality of the preparation apparatuses.

When a solid precursor and a liquid precursor are mixed together and introduced into a film formation chamber, the precursor introduction method may have a constitution which further has the steps of:

(h) mixing the solid precursor solution discharged from the preparation device with a liquid precursor; and

(i) controlling introduction speed of the liquid precursor to be mixed.

When a solid precursor and a gas precursor are mixed together and introduced into a film formation chamber, the precursor introduction method may have a constitution which further has the steps of:

(j) introducing a gas precursor into the film formation chamber; and

(k) controlling introduction speed of the gas precursor to be introduced.

The present invention resides in a film formation method for forming a film using at least a solid precursor, wherein the solid precursor is introduced into a film formation chamber by the above-mentioned precursor introduction method.

The present invention resides in a film formation method for forming a composite material film using a plurality of precursors containing at least a solid precursor, wherein a plurality of the precursors are introduced into a film formation chamber by the above-mentioned precursor introduction method for introducing a plurality of precursors containing at least a solid precursor.

The film formation method as described above is suitable as a step for forming a film on a substrate, which is one step of a semiconductor device production method.

The present invention can provide: a film formation apparatus for forming a film by a supercritical film formation method using at least a solid precursor wherein the solid precursor can be introduced into a film formation chamber at constant speed; a method for introducing the precursor; and a film formation method.

More specifically, the following effects can be exerted.

(1) Since it is not necessary to volatilize at higher temperatures in introducing a precursor, it is not required to pay attention to thermal decomposition of a precursor, which often occurs in a volatilization process.

(2) Since any precursors dissolvable in supercritical carbon dioxide can be used irrespective of its volatility and condition (gas, liquid, solid), the range of precursors capable of being selected is enlarged remarkably. The degree of dissolution in supercritical carbon dioxide is believed to be analogous to that of general alkane-type solvents, and a lot of organometal complexes can be dissolved therein.

(3) Even if, in the case of using a plurality of precursors, there is a significant difference in vapor pressure between the precursors, the precursors can be introduced into a film formation chamber at any introduction amount ratio, and resultantly, a composite material film having any composition ratio can be formed.

(4) There are independent introduction means respectively for solid, liquid and gas precursors, thus, the flow of the precursor can be introduced at any flow amount constantly without change over time.

### BRIEF DESCRIPTION OF THE DRAWINGS

FIG. 1 is a schematic view showing a constitution of one embodiment of the film formation apparatus according to the present invention.

FIG. 2 is a schematic view showing a constitution of one embodiment of the film formation apparatus according to the present invention.

FIG. 3 is a set of charts showing change of (a) solid precursor introduction speed and (b) supercritical carbon dioxide flow rate, in a precursor introduction method according to the present invention.

FIG. 4 is a set of charts showing change of solid precursor introduction speed in a conventional precursor introduction method.

### DETAILED DESCRIPTION OF PREFERRED EMBODIMENTS

In the present invention, a precursor is dissolved in supercritical carbon dioxide, and then the obtained supercritical carbon dioxide solution is introduced into a film formation chamber. Higher temperatures are not necessary to dissolve a precursor in supercritical carbon dioxide, and any precursors dissolvable in supercritical carbon dioxide can be used irrespective of its volatility and condition (gas, liquid, solid).

Also, the present invention provides: a film formation apparatus in which each of solid, liquid and gas precursors can be introduced constantly; a method for introducing the precursor; and a film formation method. The introduction speeds (mol/min.) of solid, liquid and gas precursors can respectively be controlled by the above-mentioned introduction means. Therefore, a plurality of precursors can be introduced constantly at any proportion, and a composite material film having any composition ratio can be formed with high quality and good step coverage.

According to the present invention, precursors in gas, liquid and solid conditions can be introduced into a film formation chamber by introduction means independent for respective conditions. More specifically, a solid precursor is dissolved in supercritical carbon dioxide in a high pressure container (reservoir), and then the flow of the obtained supercritical carbon dioxide solution is introduced into a film formation chamber (continuously introduced while continuously equating the flow rates of supercritical carbon dioxide at an inlet port and at an outlet port of a film formation chamber). In this case, for avoiding lowering of the introduction speed of the solid precursor with the lapse of introduction time (due to decrease in the solid precursor concentration), the solid precursor concentration is monitored by various concentration measuring means (UV-V is, FT-IR or the like). With this monitoring, the flow rate of a supercritical carbon dioxide solution containing a solid precursor is increased, to keep the introduction speed of a solid precursor constant. By this operation, constant introduction of a solid precursor is made possible. The flow rates of the liquid precursor and gas precursor are controlled by a liquid pump and a mass flow controller, respectively, and then are mixed with supercritical carbon dioxide. Thus, these precursors can be introduced constantly into a film formation chamber.

As described above, by appropriately combining three kinds of introduction means for a solid precursor, liquid precursor and gas precursor, a plurality of precursors can be introduced into a film formation chamber constantly and continuously at any introduction amount ratio and any introduction speed, and a composite material film of high quality having any composition ratio can be formed.

The constitution will concretely be explained below.

### (Film Formation Apparatus)

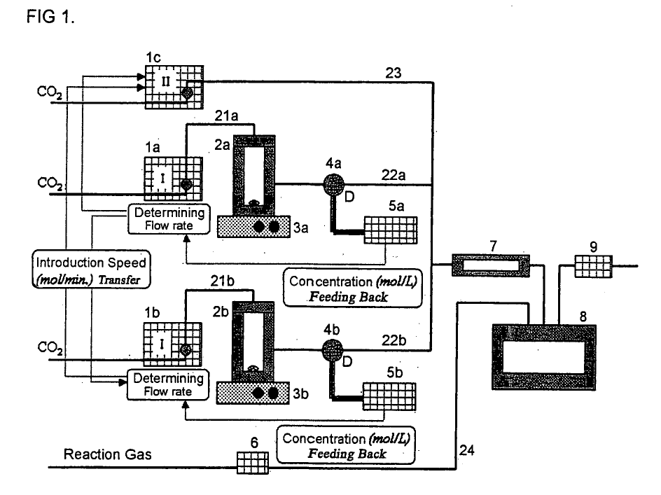

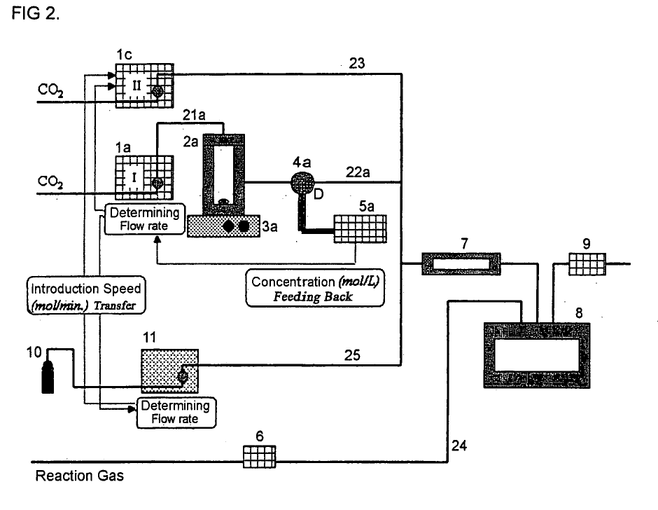

FIGS. 1 and 2 show each a schematic constitution of one embodiment of the film formation apparatus according to the present invention.

The film formation apparatus according to the present invention has, as shown in FIGS. 1 and 2, a film formation chamber 8, a solid precursor dissolution chamber 2a as a preparation device, a first supercritical carbon dioxide feeding line 21a, a detector 5a, a pump (I) 1a for supercritical carbon dioxide as a flow rate adjusting means, and a solid precursor introduction line 22a, as essential constitutions. The first supercritical carbon dioxide feeding line 21a is coupled to the solid precursor dissolution chamber 2a, through which supercritical carbon dioxide can be fed into the solid precursor dissolution chamber 2a. The solid precursor dissolution chamber 2a is coupled to the film formation chamber 8 via the solid precursor introduction line 22a, and a solid precursor solution discharged from the solid precursor dissolution chamber 2a can be introduced into the film formation chamber 8.

On the other hand, the concentration of a solid precursor in a solid precursor solution discharged from the solid precursor dissolution chamber 2a can be monitored by the detector 5a at a detection part 4a. As the detector 5a, for example, a UV-V is measuring device or FT-IR measuring device can be used. The concentration data of a solid precursor obtained in the detector 5a can be fed back to the supercritical carbon dioxide pump (I) 1a. In this constitution, the flow rate of supercritical carbon dioxide fed to the solid precursor dissolution chamber 2a by the supercritical carbon dioxide pump (I) 1a can be controlled based on the fed back concentration data. By this, the flow rate of the solid precursor solution discharged from the solid precursor dissolution chamber 2a can be controlled so that the introduction speed of the solid precursor to be introduced into the film formation chamber 8 becomes constant.

As shown in FIGS. 1 and 2, a hot plate 3a having stirring function for heating and/or stirring the inside of the solid precursor dissolution chamber 2a may be provided. Also, a back pressure adjusting device 9 for adjusting the pressure in the film formation chamber 8 may be provided.

The above-mentioned film formation apparatus has preferably a constitution having a mixing device 7, as shown in FIGS. 1 and 2. In this mixing device 7, another substance can be mixed with a solid precursor solution discharged from the solid precursor dissolution chamber 2a. Examples of the substance to be mixed include supercritical carbon dioxide, other solid precursor solutions, and liquid precursor solutions.

For providing a film formation apparatus capable of mixing a solid precursor solution and supercritical carbon dioxide, a constitution can be made in which a second supercritical carbon dioxide feeding line 23 is coupled to a mixing device 7 as shown in FIGS. 1 and 2. By this, supercritical carbon dioxide in which no solid precursor is dissolved can be fed into the mixing device 7, and a solid precursor solution and supercritical carbon dioxide can be mixed. This is effective for controlling the flow rate of supercritical carbon dioxide to be introduced into the film formation chamber 8 to be constant.

For enabling mixing of a solid precursor solution and another solid precursor solution, a constitution can be made having another part by which another solid precursor solution is introduced into a mixing device 7. More specifically, the constitution may have a solid precursor dissolution chamber 2b as a preparation device, a first supercritical carbon dioxide feeding line 21b, a detector 5b, a supercritical carbon dioxide pump (I) 1b as a flow rate adjusting means, and a solid precursor introduction line 22b, as shown in FIG. 1. The coupling conditions and functions of them are the same as described above. Also, a hot plate 3b having stirring function for heating and/or stirring the inside of the solid precursor dissolution chamber 2b may be provided. Thus, by coupling the solid precursor introduction lines 22a and 22b to the mixing device 7, another solid precursor solution can be fed into the mixing device 7, and a solid precursor solution and another solid precursor solution can be mixed.

For providing a film formation apparatus capable of mixing a solid precursor solution and a liquid precursor, a constitution can be made in which the liquid precursor introduction liner 25 is coupled to a mixing device 7 as shown in FIG. 2. By this, a liquid precursor can be introduced into the mixing device 7 from the liquid precursor storage container 10 coupled to another end of the liquid precursor introduction line 25, and a solid precursor solution and a liquid precursor can be mixed. The introduction speed of a liquid precursor can be controlled by a liquid pump 11.

For providing a film formation apparatus for performing film formation using a gas precursor together, a constitution can be made in which a gas precursor introduction line 24 is coupled to a film formation chamber 8 as shown in FIGS. 1 and 2. By this, a gas precursor can be introduced from the gas precursor introduction line 24 into the film formation chamber 8, and film formation can be performed using a gas precursor together. The introduction speed of a gas precursor can be controlled by a mass flow controller 6.

The film formation apparatus as described above is suitable as a film formation apparatus equipped on a semiconductor device production apparatus.

### (Precursor Introduction Method)

The precursor introduction method according to the present invention is a method for introducing at least a solid precursor into a film formation chamber. More specifically the method is carried out as described below.

First, a solid precursor solution is prepared by dissolving a solid precursor in supercritical carbon dioxide in a preparation device (step (a)). In the case of use of the film formation apparatus having the constitution shown in FIG. 1 or 2, supercritical carbon dioxide is fed from the first supercritical carbon dioxide feeding line 21a into the solid precursor dissolution chamber 2a containing a previously added solid precursor, whereby a solid precursor solution can be prepared. It is also possible to heat and/or stir the inside of the solid precursor dissolution chamber 2a by a hot plate 3a having stirring function.

Here, the concentration of the solid precursor in the solid precursor solution prepared is monitored (step (b)). In the case of use of the film formation apparatus having the constitution shown in FIG. 1 or 2, the concentration of the solid precursor in the solid precursor solution discharged from the solid precursor dissolution chamber 2a is monitored by a detector 5a at a detection part 4a. This monitoring can be carried out by, for example, UV-V is measurement or FT-IR measurement.

More specifically, a calibration curve graphing the relation between a detection value detected by the detector 5a and the concentration of the solid precursor is previously made. This calibration curve is made for every solid precursor to be used. Based on the actually monitored detection value, the concentration of the solid precursor is calculated using the calibration curve for the solid precursor used.

Further, the concentration of the solid precursor obtained by monitoring is fed back, and the flow rate of the solid precursor solution discharged from the preparation device is controlled so that the introduction speed of the solid precursor to be introduced into the film formation chamber becomes constant (step (c)). In the case of use of the film formation apparatus having the constitution shown in FIG. 1 or 2, this control can be carried out by the supercritical carbon dioxide pump (I) 1a. The monitoring may be intermittent or continuous.

For example, when there is obtained a result of decrease in the concentration of the solid precursor by monitoring, the flow rate of supercritical carbon dioxide fed to the solid precursor dissolution chamber 2a from the supercritical carbon dioxide pump (I) 1a is increased. On the other hand, when there is obtained a result of increase in the concentration of the solid precursor, the flow rate of supercritical carbon dioxide fed to the solid precursor dissolution chamber 2a from the supercritical carbon dioxide pump (I) 1a is decreased. By this control, the discharge speed of the solid precursor contained in the solid precursor solution discharged from the solid precursor dissolution chamber 2a can be kept constant.

Under control of the flow rate of the solid precursor solution discharged from the preparation device, the solid precursor solution discharged from the preparation device is introduced into the film formation chamber (step (d)). In the case of use of the film formation apparatus having the constitution shown in FIG. 1 or 2, the solid precursor solution discharged from the preparation device can be introduced into the film formation chamber via the solid precursor introduction line 22a. As described above, the discharge speed of the solid precursor contained in the solid precursor solution discharged from the solid precursor dissolution chamber 2a is constant, thus, the introduction speed of the solid precursor to be introduced into the film formation chamber 8 becomes constant.

In the above-mentioned precursor introduction method, it is also possible to additionally mixing supercritical carbon dioxide with the solid precursor solution discharged from the solid precursor dissolution chamber 2a (step (e)). For example, by use of a film formation apparatus having the constitution shown in FIG. 1 or 2, supercritical carbon dioxide to be additionally mixed can be fed from the second supercritical carbon dioxide feeding line 23 to the mixing device 7, and supercritical carbon dioxide can be additionally mixed with the solid precursor solution discharged from the solid precursor dissolution chamber 2a. In this operation, the feeding speed of the above-mentioned supercritical carbon dioxide to be additionally mixed is controlled so that the flow rate of supercritical carbon dioxide to be introduced into the film formation chamber becomes constant (step (f)). This control can be carried out by a supercritical carbon dioxide pump (II) 1c.

In the case of a result of decrease in the concentration of the solid precursor by monitoring by the preparation device 5a, as described above, a control is performed to increase the flow rate of supercritical carbon dioxide to be fed to the solid precursor dissolution chamber 2a by the supercritical carbon dioxide pump (I) 1a. By this control, the introduction speed of the solid precursor to be introduced into the film formation chamber 8 becomes constant, however, the flow rate of supercritical carbon dioxide to be introduced into the film formation chamber 8 also increases simultaneously. In such a case, the flow rate of supercritical carbon dioxide fed by the supercritical carbon dioxide pump (II) 1c is decreased. On the other hand, in the case of a result of increase in the concentration of a solid precursor, a control is performed to decrease the flow rate of supercritical carbon dioxide fed to the solid precursor dissolution chamber 2a by the supercritical carbon dioxide pump (I) 1a. Therefore, the flow rate of supercritical carbon dioxide fed by the supercritical carbon dioxide pump (II) 1c is increased. By this control, the flow rate of supercritical carbon dioxide to be introduced into the film formation chamber 8 can be made constant.

By the above-mentioned precursor introduction method, it is also possible to introduce a plurality of precursors containing at least a solid precursor into the film formation chamber. For example, a plurality of solid precursors can also be introduced into the film formation chamber, and a solid precursor and a liquid precursor and/or a gas precursor can also be introduced into the film formation chamber.

In the case of introduction of a plurality of solid precursors into the film formation chamber, it is possible to perform the above-mentioned steps (a) to (c) on each of a plurality of solid precursors and to mix a plurality of the solid precursor solutions discharged from a plurality of the preparation devices (step (g)). For example, by use of the film formation apparatus having the constitution shown in FIG. 1, the solid precursor solutions containing two solid precursors respectively can be prepared by the solid precursor dissolution chambers 2a and 2b, and the two solid precursor solutions discharged from the solid precursor dissolution chambers 2a and 2b can be mixed by the preparation device 7. By this, a plurality of solid precursors can be introduced into the film formation chamber 8 under condition of mixing at any ratio.

In this case, it is possible to control the flow rate of supercritical carbon dioxide fed to the solid precursor dissolution chambers 2a and 2b by the supercritical carbon dioxide pumps (I) 1a and 1b, respectively. It is preferable to mutually feed back the concentration data and flow rate data of the solid precursor also between the supercritical carbon dioxide pumps (I) 1a and 1b.

In the case of introduction of a solid precursor and a liquid precursor into the film formation chamber, it is possible to mix the solid precursor solution discharged from the preparation device and the liquid precursor (step (h)). For example, by use of the film formation apparatus having the constitution shown in FIG. 2, the liquid precursor to be mixed can be fed to the mixing device 7 from the liquid precursor introduction line 25, and the solid precursor solution discharged from the solid precursor dissolution chamber 2a and the liquid precursor can be mixed. In this case, the introduction speed of the liquid precursor to be mixed is controlled (step (i)). This control can be carried out by the liquid pump 11. By this, the solid precursor and the liquid precursor can be introduced into the film formation chamber 8 under condition of mixing at any ratio.

In the case of introduction of a solid precursor and a gas precursor into a film formation chamber, it is also possible to introduce the gas precursor into the film formation chamber (step (j)). For example, by use of the film formation apparatus having the constitution shown in FIGS. 1 and 2, the gas precursor can be introduced into the film formation chamber 8 from the gas precursor introduction liner 24. In this case, the introduction speed of the gas precursor to be introduced is controlled (step (k)). This control can be carried out by the mass flow controller 6. By this, the gas precursor and the solid precursor can be introduced into the film formation chamber 8 at any ratio.

### (Film Formation Method)

The film formation method according to the present invention is a method for forming a film using at least a solid precursor, and performed by introducing various precursors containing a solid precursor into a film formation chamber by the above-mentioned precursor introduction method. The above-mentioned film formation method can also be a method for forming a composite material film using a plurality of precursors containing at least a solid precursor. In this case, various precursors containing a solid precursor are introduced into the film formation chamber by the above-mentioned method for introducing a plurality of solid precursors into the film formation chamber.

Such a film formation method is suitable as the step for forming a film on a base plate, which is one step of a semiconductor device production method.

### EXAMPLE

Film formation of Sr—Ti—O (STO) as a ferroelectric will be illustrated below as an example. For film formation of STO, a system as shown in FIG. 2 is optimum.

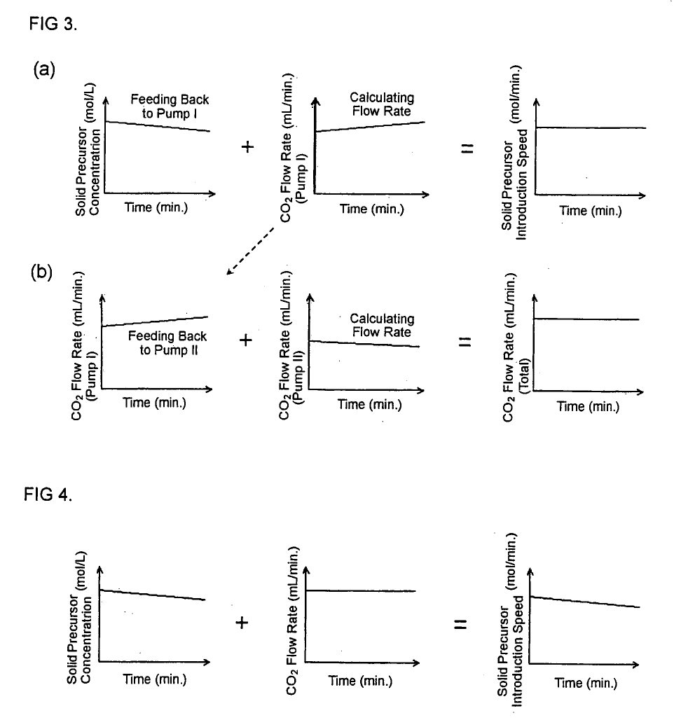

A Sr precursor (Strontium 2,2,6,6-tetramethyl-3,5-heptanedionate, THD) as a solid precursor is dissolved in supercritical carbon dioxide in the solid precursor dissolution chamber 2a. The concentration of the Sr precursor in the solid precursor solution discharged from the solid precursor dissolution chamber 2a is calculated from the measured value by the detector 5a (UV-V is or FT-IR and the like), and the concentration data (mol/L) is fed back to the supercritical carbon dioxide pump (I) 1a. Then, the supercritical carbon dioxide flow rate (mL/min.) is adjusted so as to obtain any Sr precursor introduction speed (mol/min.). The flow rate of supercritical carbon dioxide is changed (increased) as needed with change (decrease) of the Sr precursor concentration (FIG. 3(a)). Compensation is performed using the supercritical carbon dioxide pump (II) to keep constant the flow rate (mL/min.) of supercritical carbon dioxide to be introduced into a film formation chamber, referring to the above-mentioned flow rate (mL/min.) of supercritical carbon dioxide (FIG. 3(b)). By this, the Sr precursor introduction speed (mol/min.) and the flow rate (mL/min.) of supercritical carbon dioxide can be kept constant.

In conventional methods, the Sr precursor introduction speed (mol/min.) changes (decreases) with change (decrease) in the Sr precursor concentration, since the supercritical carbon dioxide flow rate (mL/min.) is not adjusted (FIG. 4).

The flow rate (mol/min.) of a Ti precursor (Titanium isopropoxide, O-i-Pr) as a liquid precursor is adjusted by the liquid pump 11 so as to give any Sr:Ti ratio, referring to the introduction speed (mol/min.) of the above-mentioned Sr precursor. The introduction speed of oxygen as a gas precursor can be controlled using the high pressure mass flow controller 6.

Thus, precursors each of which has a different volatility and condition can be introduced easily into a reactor at any introduction amount ratio.

Also ferroelectric films having three metal atoms such as Ba—Sr—Ti—O (BST) can be formed by using the similar apparatus. Many kinds of Ba precursors have low volatility like the Sr precursor. Therefore, each of precursors can be easily introduced into a film formation chamber at any Ba:Sr:Ti ratio by using a film formation apparatus having two solid precursor lines (for Ba and Sr) and one liquid precursor line (for Ti).

What is claimed is:

1. A film formation apparatus for forming a film using at least a solid precursor, comprising:
a film formation chamber;
a preparation device for preparing a solid precursor solution by dissolving the solid precursor in supercritical carbon dioxide;
a first supercritical carbon dioxide feeding line for feeding supercritical carbon dioxide into the preparation device;
a detector for monitoring concentration of the solid precursor in the solid precursor solution;
a flow rate adjusting means for controlling flow rate of the solid precursor solution discharged from the preparation device so that introduction speed of the solid precursor to be introduced into the film formation chamber becomes constant by feeding back the concentration of the solid precursor obtained in the detector; and
a solid precursor introduction line for introducing the solid precursor solution discharged from the preparation device into the film formation chamber.

2. The film formation apparatus according to claim 1, wherein the detector is a UV-V is measuring apparatus or an FT-IR measuring apparatus.

3. The film formation apparatus according to claim 1, further comprising a mixing device for mixing the solid precursor solution discharged from the preparation device with another substance.

4. The film formation apparatus according to claim 3, further comprising a second supercritical carbon dioxide feeding line for feeding supercritical carbon dioxide into the mixing device.

5. The film formation apparatus according to claim 3, comprising a plurality of the preparation devices, the first supercritical carbon dioxide feeding lines, the detectors, the flow rate adjusting means and the solid precursor introduction lines, wherein a plurality of the solid precursor solutions discharged from a plurality of the preparation devices are mixed together in the mixing device.

6. The film formation apparatus according to claim 3, further comprising a liquid precursor introduction line for introducing a liquid precursor into the mixing device.

7. The film formation apparatus according to claim 1, further comprising a gas precursor introduction line for introducing a gas precursor into the film formation chamber.

8. A semiconductor device production apparatus comprising the film formation apparatus according to claim 1.

9. A precursor introduction method for introducing at least a solid precursor into a film formation chamber, comprising the steps of:
(a) preparing a solid precursor solution by dissolving the solid precursor in supercritical carbon dioxide in a preparation device;
(b) monitoring concentration of the solid precursor in the solid precursor solution;
(c) controlling flow rate of the solid precursor solution discharged from the preparation device so that introduction speed of the solid precursor to be introduced into the film formation chamber becomes constant by feeding back the concentration of the solid precursor obtained by the monitoring; and
(d) introducing the solid precursor solution discharged from the preparation device into the film formation chamber.

10. The precursor introduction method according to claim 9, wherein the monitoring in the step (b) is carried out by UV-V is measurement or FT-IR measurement.

11. The precursor introduction method according to claim 9, further comprising the steps of:
(e) additionally mixing supercritical carbon dioxide with the solid precursor solution discharged from the preparation device; and
(f) controlling feeding speed of the supercritical carbon dioxide to be additionally mixed so that flow rate of supercritical carbon dioxide to be introduced into the film formation chamber becomes constant.

12. The precursor introduction method according to claim 9, wherein the steps (a) to (c) are performed on each of a plurality of the solid precursors; and further comprising the step of:
(g) mixing a plurality of the solid precursor solutions discharged from a plurality of the preparation apparatuses.

13. The precursor introduction method according to claim 9, further comprising the steps of:
(h) mixing the solid precursor solution discharged from the preparation device with a liquid precursor; and
(i) controlling introduction speed of the liquid precursor to be mixed.

14. The precursor introduction method according to claim 9, further comprising the steps of:
(j) introducing a gas precursor into the film formation chamber; and
(k) controlling introduction speed of the gas precursor to be introduced.

15. A film formation method for forming a film using at least a solid precursor, wherein the solid precursor is introduced into a film formation chamber by the precursor introduction method according to claim 9.

16. A film formation method for forming a composite material film using a plurality of precursors containing at least a solid precursor, wherein a plurality of the precursors are introduced into a film formation chamber by the precursor introduction method according to claim 12.

17. A semiconductor device production method, comprising the step of forming a film on a substrate by the film formation method according to claim 15.
